(19) United States
(12) Patent Application Publication
(10) Pub. No.: US 2022/0037161 A1
(43) Pub. Date: Feb. 3, 2022

(54) Semiconductor Etching Method

(71) Applicant: CHANGXIN MEMORY TECHNOLOGIES, INC., Hefei City (CN)

(72) Inventor: Lei YANG, Hefei (CN)

(73) Assignee: CHANGXIN MEMORY TECHNOLOGIES, INC., Hefei City (CN)

(21) Appl. No.: 17/501,164

(22) Filed: Oct. 14, 2021

Related U.S. Application Data
(63) Continuation of application No. PCT/CN2021/081738, filed on Mar. 19, 2021.

(30) Foreign Application Priority Data
Mar. 23, 2020 (CN) 202010206328.4

(51) Int. Cl. H01L 21/308; H01L 21/265; H01L 21/3213

(52) U.S. Cl. CPC H01L 21/3086; H01L 21/32139; H01L 21/265

(57) ABSTRACT

A semiconductor etching method that comprises providing a material layer to be etched; sequentially forming on the material layer to be etched a first mask layer and a second mask layer that covers the first mask layer; patterning the second mask layer to form differently sized opening patterns that expose the first mask layer with differently sized regions; performing ion implantation on the exposed regions on the basis of the opening patterns; ion implantation concentration in each region is in direct proportion to the width of the region, and material etching removal rate of the ion-implanted region is in reverse proportion to the ion implantation concentration in the region; and basing on the opening patterns to etch the ion-implanted regions into the material layer to be etched to form grooves identical in size with the opening patterns, wherein depths of the grooves are approximate to or identical with one another.

### CROSS-REFERENCE TO RELATED APPLICATIONS

This application is a continuation of International Patent Application No. PCT/CN2021/081738 filed on Mar. 19, 2021, which claims priority to Chinese Patent Application No. 202010206328.4 filed Mar. 23, 2020. The above-referenced applications are incorporated herein by reference in their entirety.

### TECHNICAL FIELD

The present application relates to the field of semiconductor technology, and more particularly to a semiconductor etching method.

### BACKGROUND

In the current technique for fabricating semiconductors, the pattern design of landing pad layout is complicated, the etching width usually ranges from ten to hundreds nanometers. This leads to loading effect related to aspect ratio dependent etching, ARDE, in the process of etching the material layer to be etched, and this effect mainly manifests itself in different etching depths of differently sized patterns on the material layer to be etched—wider patterns are deeply etched, while narrower patterns are shallowly etched.

It is therefore needed to search for a measure to solve the above problem concerning etch uniformity caused by loading effect due to patterns of differing widths.

### SUMMARY

According to the embodiments of the present application, there is provided a semiconductor etching method.

The semiconductor etching method comprises:

providing a material layer to be etched;

sequentially forming on the material layer to be etched a first mask layer and a second mask layer that covers the first mask layer; patterning the second mask layer to form differently sized opening patterns that expose the first mask layer with differently sized regions;

performing ion implantation on the exposed regions on the basis of the opening patterns; ion implantation concentration in each region is in direct proportion to the width of the region, and material etching removal rate of the ion-implanted region is in reverse proportion to the ion implantation concentration in the region;

and basing on the opening patterns to etch the ion-implanted regions into the material layer to be etched to form grooves identical in size with the opening patterns, wherein depths of the grooves are approximate to or identical with one another.

### BRIEF DESCRIPTION OF DRAWINGS

The aforementioned and other objectives, characteristics and advantages of the present application will become more lucid through more detailed description of the embodiments preferred by the present application as illustrated in the accompanying drawings. In the entire accompanying drawings, identical reference numerals indicate identical parts, and the drawings are not proportionally scaled on intention on the basis of actual sizes, as the gist lies in illustrating the essence of the present application.

FIG. 1 is a diagram schematically illustrating the cross section of a prior-art semiconductor structure before etching and including a patterned hard mask layer, a mask layer, an amorphous carbon layer and a material layer to be etched;

FIG. 2 is a diagram schematically illustrating the cross section of a prior-art semiconductor structure in the process of etching and including a patterned hard mask layer, an amorphous carbon layer and a material layer to be etched;

FIG. 3 is a diagram schematically illustrating the cross section of a prior-art material layer to be etched after etching has been completed;

FIG. 4 is a flowchart illustrating a semiconductor etching method according to the present application;

FIG. 5 is a diagram schematically illustrating the cross section of a structure with a patterned hard mask layer, a second mask layer, a first mask layer and a material layer to be etched formed thereon as obtained via the semiconductor etching method in one embodiment of the present application;

FIG. 6 is a diagram schematically illustrating the cross section of a structure with a patterned mask layer, a first mask layer and a material layer to be etched obtained by pattern-processing the cross-sectional structure shown in FIG. 5 in one embodiment of the present application;

FIG. 7 is a diagram schematically illustrating the cross-sectional structure shown in FIG. 6 during process of ion implantation in one embodiment of the present application;

FIG. 8A is a diagram schematically illustrating partial structure of the relationship among implantation angle of ions, size and width of the smallest opening pattern and thickness of the patterned mask layer during first ion implantation of regions in one embodiment of the present application;

FIG. 8B is a diagram schematically illustrating partial structure of the relationship among implantation angle of ions, size and width of the smallest opening pattern and thickness of the patterned mask layer during second ion implantation of regions in one embodiment of the present application;

FIG. 9 is a diagram schematically illustrating the cross section of a structure after ion implantation with a patterned mask layer, a first mask layer and a material layer to be etched formed thereon as obtained via the semiconductor etching method in one embodiment of the present application;

FIG. 10 is a diagram schematically illustrating the relationship between ion implantation concentration and size and width of a region in the semiconductor etching method provided by an embodiment of the present application; and

FIG. 11 illustrates a material layer to be etched having grooves of identical depth obtained after etching via the semiconductor etching method provided by an embodiment of the present application.

### DESCRIPTION OF EMBODIMENTS

In order to make more lucid and understandable the aforementioned objectives, characteristics and advantages of the present application, detailed explanations will be made below to the specific embodiments of the present application in conjunction with the accompanying drawings. The explanations below enunciate many specific details to facilitate fuller comprehension of the present application. However, the present application can be implemented by many modes other than those described in this context, and technicians skilled in the art may make similar improvements without departing from the spirit of the present application, so the present application is not restricted by the specific embodiments made public below.

Unless otherwise defined, all technical and scientific terms used in this context are identical in meaning to those conventionally understood by persons skilled in the art. Technical terms used in the Description of the present application are merely intended to describe specific embodiments, rather than to restrict the present application. The wording “and/or” used in this context means the inclusion of one or more of any random and all combination(s) of the relevantly listed items.

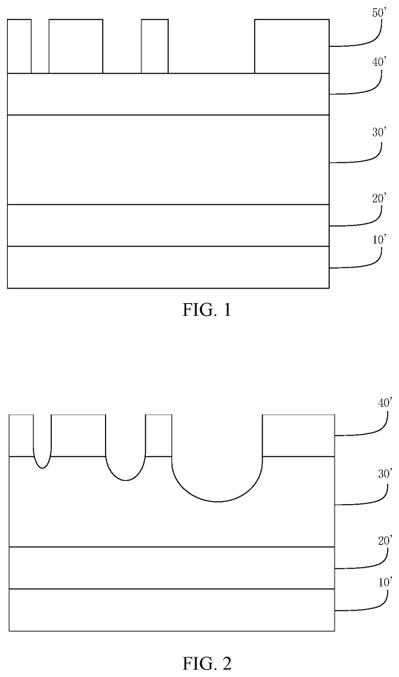

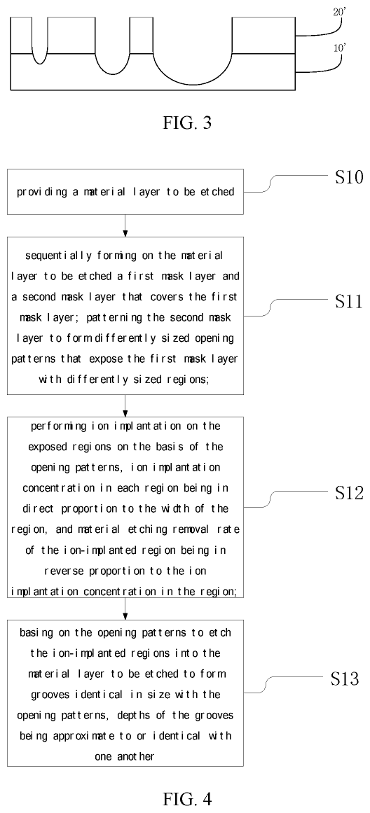

As found by the inventor of the present application at work, there exists a problem of etch non-uniformity during the process of etching a first metal layer, specifically, as shown by FIGS. 1-3, which are diagrams schematically illustrating cross-sectional structures in the process of etching the first metal layer in the prior-art semiconductor etching technique; of these, FIG. 1 shows the cross section of a semiconductor structure before etching, the structure comprises a material layer to be etched of silicon nitride 10′ (SiN), and a metal wolframium 20′ (W), and on the material layer to be etched are sequentially formed an amorphous carbon layer 30′ (ACL), a mask layer 40′ of silicon oxynitride (SiON) and a patterned hard mask layer 50′ of tetra-ethyl-ortho-silicate (TEOS); as shown in FIG. 2, which is a diagram schematically illustrating the cross section of a semiconductor in the process of etching, it can be seen that the etching removal rate at the opening of a wider pattern is quicker than the etching removal rate at the opening of a narrower pattern, and this results in the fact that the depth of the groove etched at the opening of the wider pattern is always deeper than the depth of the groove etched at the opening of the narrower pattern; when etching is complete, as shown in FIG. 3, grooves etched in the material layers to be etched 10′, 20′ are apparently problematic in etch non-uniformity as wider patterns are deeply etched while narrower patterns are shallowly etched due to loading effect.

Accordingly, on the basis of the above problem found by the inventor, the present application provides a semiconductor etching method capable of ensuring etch uniformity of the material layer to be etched.

In order to make the aforementioned objectives, characteristics and advantages of the present application more apparent and comprehensible, detailed description is made below to the specific embodiments of the present application in conjunction with the accompanying drawings.

Referring to FIG. 4, specifically, a semiconductor etching method proposed by the present application comprises the following steps:

S10: providing a material layer to be etched;

S11: sequentially forming on the material layer to be etched a first mask layer and a second mask layer that covers the first mask layer; patterning the second mask layer to form differently sized opening patterns that expose the first mask layer with differently sized regions;

S12: performing ion implantation on the exposed regions on the basis of the opening patterns; ion implantation concentration in each region is in direct proportion to the width of the region, and material etching removal rate of the ion-implanted region is in reverse proportion to the ion implantation concentration in the region; and

S13: basing on the opening patterns to etch the ion-implanted regions into the material layer to be etched to form grooves identical in size with the opening patterns, where depths of the grooves are approximate to or identical with one another. As should be noted, the wording “approximate to” used in this context means that the depths of the various grooves are all within a certain range, to be regarded as being approximate in the technique.

By allocating ion implantation concentrations of various regions in the first mask layer, the present application achieves the objective of adjusting etching removal rates of the various regions, so that the etching removal rates of the regions with differing opening sizes become controllable.

To facilitate description, sizes of the opening patterns are referred to as “big”, “medium” and “small” in this embodiment, specifically, the sizes are divided into big, medium and small widths. However, as should be noted, the present application makes no attempt to define the sizes of the opening patterns.

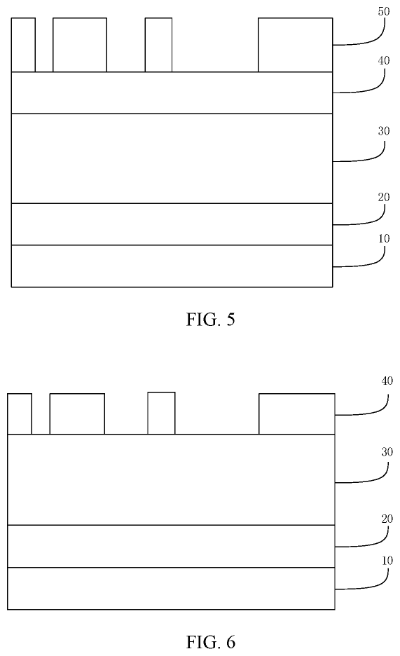

Referring to FIGS. 5-8, by way of an example, the second mask layer 40 can comprise, but is not restricted to comprise, a silicon oxynitride layer (SiON); the first mask layer 30 can comprise, but is not restricted to comprise, an amorphous carbon layer (ACL) and an un-doped poly layer, and the implanted ions comprise, but are not restricted to comprise, carbon-like ions. These are so selected because other ions of the amorphous carbon layer do not affect the carbon ion concentration, and carbon-like ions are neutral tetravalent without polarity, so carbon-like ions do not change characteristics of other materials when implanted.

Exemplarily and preferably, it is selected to simultaneously perform ion implantation on the various exposed regions, and ion implantation time is the same for all regions, so as to make the ion implantation process simple and highly efficient.

Exemplarily, as shown in FIG. 7, as should be noted, in order to achieve the effect that ion implantation concentrations in the regions of different openings are different, the ion implantation process should be preferably completed via the mode of two angled implantations; specifically, the step of performing ion implantation on the exposed regions on the basis of the opening patterns may comprise the following steps:

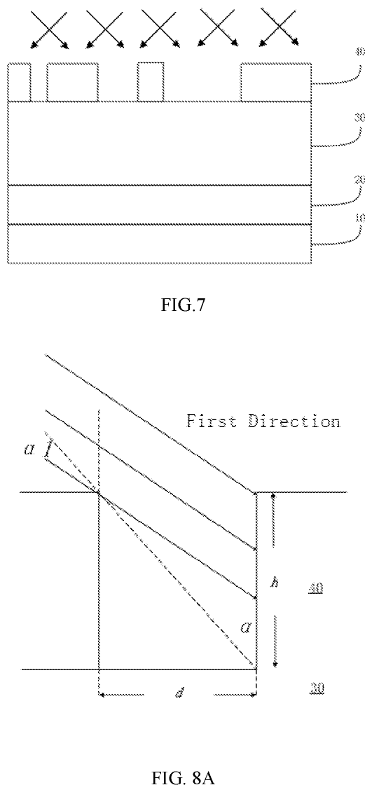

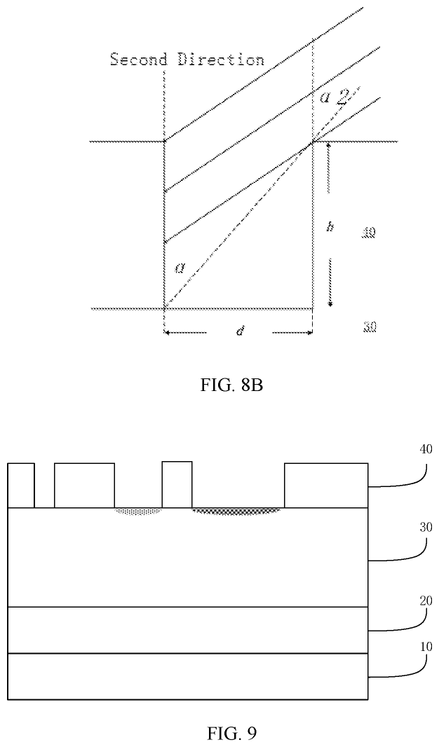

as shown in FIGS. 8A and 8B, performing first ion implantation on the exposed regions on the basis of the opening patterns, process of the first ion implantation including performing ion implantation of a first incidence angle along a first direction, angle α1 of the first incidence angle being sized as an comprised angle between the first direction and a normal direction; performing second ion implantation on the exposed regions on the basis of the opening patterns, process of the second ion implantation including performing ion implantation of a second incidence angle along a second direction, angle α2 of the second incidence angle being sized as an comprised angle between the second direction and the normal direction; wherein the first direction and the second direction are different from each other, and the angle of the first incidence angle and the angle of the second incidence angle may be equal to or different from each other, in the case they are equal, implanted ions within the same region are more uniformly distributed. As should be noted, the “normal” here indicates the dotted line that is perpendicular to the surface of the second mask layer 40. Besides, the ion implantation angle implied here is considered with the ion generator as a point of origin.

In another example, as shown in FIGS. 8A and 8B, let the angle α1 of the first incidence angle and the angle α2 of the second incidence angle both greater than α, α=arctg(d/n), where h is thickness of the patterned second mask layer, and d is width of the opening pattern with the smallest width—such design makes it impossible for ions to be implanted from the place with the smallest width of the opening pattern. The incidence angles are in the wide range of 5° to 25°.

As shown in FIG. 9, during the aforementioned process of two angled ion implantations, since ions in the regions with small opening sizes are mostly blown to the sidewall of the second mask layer 40 and cannot reach the first mask layer 30, so ions in the regions with small opening sizes cannot be implanted into the first mask layer 30 and hence the implantation concentrate is least there, and ions in the regions with big opening sizes can reach the first mask layer 30, and hence the ion implantation concentrate is great there, while ion implantation concentration in the regions with medium opening sizes is therebetween; through the two differently angled implantations, it is possible to achieve the effect that ion implantation concentrations in various regions are in direct proportion to their widths, and uniformity of ion implantation concentrations can be guaranteed at the same time.

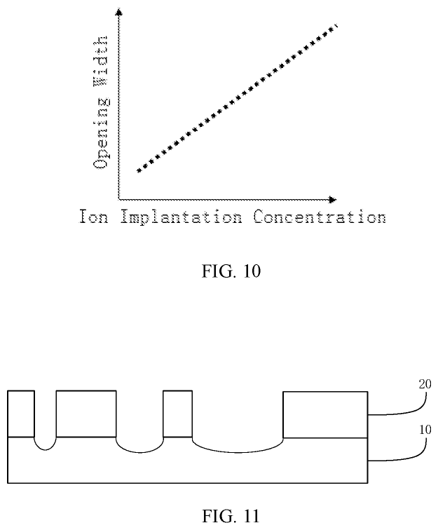

In conjunction with FIG. 10, illustrated is the relationship between the ion implantation concentration and the size and width of a region in the semiconductor etching method of the present application, where the horizontal coordinate indicates the ion implantation concentration, and the longitudinal coordinate indicates the size and width of the opening pattern. As can be seen from the Figure, to achieve etch uniformity of the present application, ion implantation concentrations and widths of various regions should be directly proportional. That is to say, in this embodiment, etching rate of a region with small opening size>etching rate of a region with medium opening size>etching rate of a region with big opening size, thus the etching rate of a region with small opening size is relatively quicker, while etching rate of a region with big opening size is relatively slower, so as to compensate for prior-art differentials between etching removal rates of differently sized pattern openings in the etching process.

Exemplarily, in order to achieve the effect that ion implantation concentrations in regions with different opening sizes are different from one another, in addition to employing the aforementioned mode of sequential angled implantations in the ion implantation process, the same effect can also be achieved through the mode of divided times and divided regions. Although the mode of divided times and divided regions for ion implantation is more complicated than the aforementioned mode of sequential angled implantations, higher precision requirement can be achieved thereby, and this mode can likewise achieve the technical effect that ion implantation concentrations in various regions are directly proportional to the widths of these regions. Specifically, in one example, the step of performing ion implantation on the exposed regions on the basis of the opening patterns can comprise the following steps:

performing ion implantation on the regions on the basis of the opening patterns, implantation direction of ions in the process of the ion implantation being perpendicular to the second mask layer 40—namely implantation along the normal direction; and

shielding those regions that reach a required ion implantation concentration once predetermined times are past, and ending the process of ion implantation until ion implantation concentrations in all regions meet the requirement.

Taking for example that the sizes of the opening patterns are referred to as “big”, “medium”, and “small” in this embodiment, the aforementioned ion implantation process can specifically comprise the following steps:

shielding the region with the smallest-sized opening pattern and having reached the required ion implantation concentration after a first time is past;

shielding the region with the medium-sized opening pattern and having reached the required ion implantation concentration again after a second time is past; and

ending ion implantation when the region with the biggest-sized opening pattern has also reached the required ion implantation concentration after a third time is past. By now, ion implantation concentrations of all regions meet the requirement.

By way of example, the process of performing ion implantation on the exposed regions on the basis of the opening patterns can also employ an ion implantation mode that combines the aforementioned perpendicular ion implantation and angled ion implantations, of which the angled ion implantations can be further subdivided into plural rounds of angled ion implantations.

Preferably, in one example, doping gas in the process of ion implantation has a flow rate of 10˜500 sccm.

By way of example, the step of sequentially forming on the material layer to be etched a first mask layer and a second mask layer specifically comprises the following steps:

forming a first mask layer 30 on surface of the material layer to be etched;

forming a second mask layer 40 on surface of the first mask layer 30;

forming a patterned hard mask layer 50 on surface of the second mask layer 40;

performing a patterning process on the second mask layer 40 on the basis of the patterned hard mask layer 50, to obtain the patterned second mask layer 40; and

removing the patterned hard mask layer 50. As it is notable, the patterned hard mask layer 50 can either be separately removed or used up in the patterning process.

By way of example, the patterned hard mask layer 50 comprises, but is not restricted to comprise, an ethyl orthosilicate (TEOS) hard mask layer. Under the material layer to be etched is disposed an etch stop layer, which adjoins the material layer to be etched.

By way of example, the patterned hard mask layer 50 can be formed with the required patterns through photoresistive coating, exposing, or developing, and the patterns are then transferred by etching onto the hard mask layer to obtain the patterned hard mask layer 50. Preferably, Litho-Etch-Litho-Etch (LELE) technique can also be employed to form more refined patterns in the hard mask layer; this technique enables better decomposition of patterns originally required to be formed in the same and single photoresist, so as to solve the problem that photoresist patterns are unduly dense.

By way of example, the material layer to be etched comprises a wolframium layer 20 (W), the etch stop layer comprises a silicon nitride layer 10 (SiN), and etching of the grooves stops in the silicon nitride layer 10, as shown in FIG. 11.

The various technical features of the aforementioned embodiments can be randomly combined; for the sake of brevity, all possible combinations of the various technical features of the aforementioned embodiments are not exhausted; however, insofar as the combinations of the technical features are not contradictory to one another, they shall all be regarded as within the scope described in this description.

The aforementioned embodiments merely indicate several modes to implement the present application, and their descriptions are relatively specific and detailed, but they should not be therefore understood as restriction to the inventive patent scope. As should be pointed out, persons ordinarily skilled in the art may make various modifications and improvements without departing from the conception of the present application, and all such modifications and improvements shall fall within the protection scope of the present application. Accordingly, the protection scope of the present application shall be as claimed in the attached claims.

What is claimed is:

1. A semiconductor etching method, comprising:
providing a material layer to be etched;
sequentially forming on the material layer to be etched a first mask layer and a second mask layer that covers the first mask layer; patterning the second mask layer to form differently sized opening patterns that expose the first mask layer with differently sized regions;
performing ion implantation on the exposed regions on the basis of the opening patterns, wherein ion implantation concentration in each region is in direct proportion to the width of the region, and material etching removal rate of the ion-implanted region is in reverse proportion to the ion implantation concentration in the region; and
basing on the opening patterns to etch the ion-implanted regions into the material layer to be etched to form grooves identical in size with the opening patterns, wherein depths of the grooves are approximate to or identical with one another.

2. The semiconductor etching method according to claim 1, wherein the second mask layer comprises a silicon oxynitride layer; the first mask layer comprises an amorphous carbon layer, and the implanted ions comprise carbon-like ions.

3. The semiconductor etching method according to claim 1, wherein ion implantation is performed on the exposed regions simultaneously, and ion implantation time is the same for all regions.

4. The semiconductor etching method according to claim 1, wherein performing ion implantation on the exposed regions on the basis of the opening patterns comprises the following steps:
performing first ion implantation on the exposed regions on the basis of the opening patterns, process of the first ion implantation including performing ion implantation of a first incidence angle along a first direction, angle of the first incidence angle being sized as an comprise angle between the first direction and a normal direction;
performing second ion implantation on the exposed regions on the basis of the opening patterns, process of the second ion implantation including performing ion implantation of a second incidence angle along a second direction, angle of the second incidence angle being sized as an comprised angle between the second direction and the normal direction; wherein
the first direction and the second direction are different from each other, and the angle of the first incidence angle and the angle of the second incidence angle are equal to each other.

5. The semiconductor etching method according to claim 4, wherein the angle of the first incidence angle and the angle of the second incidence angle are both greater than α;
$$α = arc tg ( \frac{d}{h} ) ,$$
wherein h is thickness of the patterned second mask layer, and d is width of the opening pattern with the smallest width.

6. The semiconductor etching method according to claim 1, wherein performing ion implantation on the exposed regions on the basis of the opening patterns comprises the following steps:
performing ion implantation on the exposed regions on the basis of the opening patterns, implantation direction of ions in the process of the ion implantation being perpendicular to the second mask layer; and
shielding those regions that reach a required ion implantation concentration once predetermined times are past, and ending the process of ion implantation until all regions reach the required ion implantation concentration.

7. The semiconductor etching method according to claim 6, wherein shielding those regions that reach a required ion implantation concentration once predetermined times are past and ending the process of ion implantation until all regions reach the required ion implantation concentration comprises the following steps:
shielding the region with the smallest-sized opening pattern and having reached the required ion implantation concentration after a first time is past;
shielding the region with the medium-sized opening pattern and having reached the required ion implantation concentration after a second time is past; and
ending the process of ion implantation when the region with the biggest-sized opening pattern has reached the required ion implantation concentration after a third time is past.

8. The semiconductor etching method according to claim 1, wherein sequentially forming on the material layer to be etched a first mask layer and a second mask layer comprises the following steps:
forming the first mask layer on surface of the material layer to be etched;
forming the second mask layer on surface of the first mask layer;
forming a patterned hard mask layer on surface of the second mask layer; and
performing a patterning process on the second mask layer on the basis of the patterned hard mask layer, to obtain the patterned second mask layer.

9. The semiconductor etching method according to claim 8, further comprising a step of removing the patterned hard mask layer.

10. The semiconductor etching method according to claim 9, wherein the patterned hard mask layer is separately removed or used up in the patterning process.

11. The semiconductor etching method according to claim 8, wherein the hard mask layer comprises an ethyl orthosilicate hard mask layer.

12. The semiconductor etching method according to claim 1, wherein under the material layer to be etched is disposed an etch stop layer, which adjoins the material layer to be etched.

13. The semiconductor etching method according to claim 12, wherein the material layer to be etched comprises a wolframium layer, the etch stop layer comprises a silicon nitride layer, and etching of the grooves stops in the silicon nitride layer.

14. The semiconductor etching method according to claim 4, wherein doping gas in the process of ion implantation has a flow rate of 10˜500 sccm.

15. The semiconductor etching method according to claim 4, wherein the angle of the first incidence angle and the angle of the second incidence angle are 5° to 25°.
